(19) United States
(12) Patent Application Publication
(10) Pub. No.: US 2025/0142799 A1
(43) Pub. Date: May 1, 2025

(54) Layout pattern of static random-access memory

(71) Applicant: UNITED MICROELECTRONICS CORP., Hsin-Chu City (TW)

(72) Inventors: Chun-Yen Tseng, Tainan City (TW); Yu-Tse Kuo, Tainan City (TW); Shu-Ru Wang, Taichung City (TW); Tsung-Hsun Wu, Kaohsiung City (TW); Liang-Wei Chiu, Tainan City (TW); Chun-Hsien Huang, Tainan City (TW)

(73) Assignee: UNITED MICROELECTRONICS CORP., Hsin-Chu City (TW)

(21) Appl. No.: 18/398,227

(22) Filed: Dec. 28, 2023

(30) Foreign Application Priority Data
Nov. 29, 2023 (TW) 112146351

(51) Int. Cl. H10B 10/00

(52) U.S. Cl. CPC H10B 10/12

(57) ABSTRACT

The invention provides a layout pattern of static random-access memory (SRAM), which comprises a substrate, wherein a plurality of diffusion regions and a plurality of gate structures are located on the substrate to form a plurality of transistors, wherein the plurality of gate structures comprise a first gate structure, which has a stepped shape when viewed from a top view, and the first gate structure spans a first diffusion region and a second diffusion region to form a first access transistor (PG1), wherein the first diffusion region is adjacent to and in direct contact with the second diffusion region.

### BACKGROUND OF THE INVENTION

### 1. Field of the Invention

The invention relates to a static random access memory (SRAM), in particular to a static random access memory (SRAM) layout pattern with an L-shaped gate structure and body contact.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer systems as a cache memory.

### SUMMARY OF THE INVENTION

The invention provides a layout pattern of static random-access memory (SRAM), which comprises a substrate, wherein a plurality of diffusion regions are located on the substrate, the diffusion regions at least comprises a first diffusion region, a second diffusion region, a third diffusion region and a fourth diffusion region, a plurality of gate structures are located on the substrate, and each gate structure extends along a first direction (X direction) and spans the plurality of diffusion regions to form a plurality of transistors, wherein the plurality of transistors include a first pull-up transistor (PU1), a first pull-down transistor (PD1), a second pull-up transistor (PU2), a second pull-down transistor (PD2), a first access transistor (PG1) and a second access transistor (PG2). The plurality of gate structures include a first gate structure, the first gate structure has a stepped shape when viewed from a top view, and the first gate structure spans the first diffusion region and the second diffusion region to form a first access transistor (PG1), wherein the first diffusion region is adjacent to and in direct contact with the second diffusion region.

The present invention is characterize by providing an improved layout pattern of static random access memory, which include some diffusion regions with opposite electrical properties, which are located beside that diffusion region below the gate of each transistor. In this way, the charge accumulated under the gate structure can flow out through the diffusion region, and then the charge is released through the contact structure, so as to avoid affecting the electrical properties of the transistor and improve the product yield. In addition, the gate structure is designed in a stepped shape (from the top view), which has the advantages of avoiding the close distance between adjacent gates, staggering the word line contact with the diffusion region, reducing the rounding of the pattern, and so on, so the process yield can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a circuit diagram of an SRAM cell.

FIG. 2 shows a schematic cross-sectional structure of a transistor.

FIG. 3 is a layout diagram of a static random access memory (SRAM) cell according to a first preferred embodiment of the present invention.

FIG. 4A shows an enlarged schematic diagram of the first gate structure G1 and its vicinity in FIG. 3.

FIG. 4B shows an enlarged schematic diagram of the first gate structure G1 and its vicinity in another embodiment.

FIGS. 5-7 are layout diagrams of static random access memory (SRAM) cells according to a first preferred embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

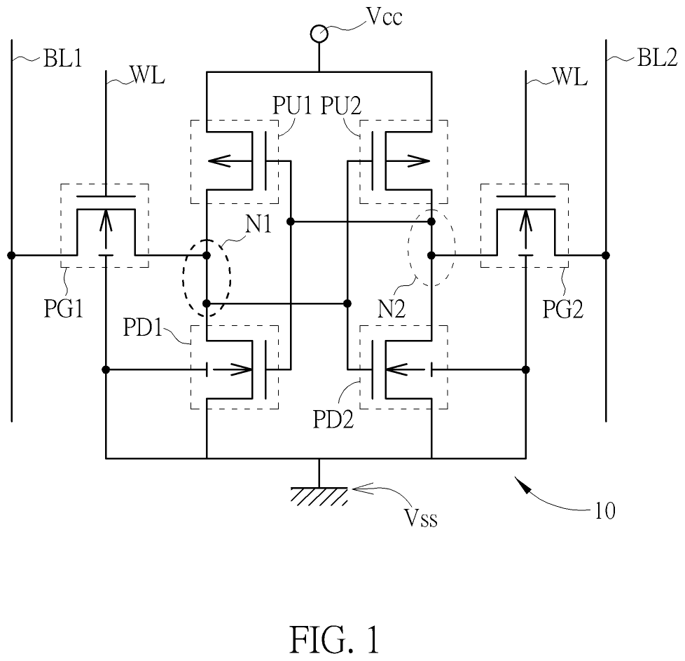

Please refer to FIG. 1, which shows a circuit diagram of a static random access memory (SRAM) cell of the present invention. In this embodiment, an SRAM cell 10 is preferably composed of a first pull-up transistor PU1, a second pull-up transistor PU2, a first pull-down transistor PD1, a second pull-down transistor PD2, and a first access transistor PG1 and a second access transistor PG2 form a flip-flop, wherein the first pull-up transistor PU1 and the second pull-up transistor PU2, the first pull-down transistor PD1 and the second pull-down transistor PD2 form a latch circuit, so that data can be latched at a storage node N1 or N2. In addition, the first pull-up transistor PU1 and the second pull-up transistor PU2 are used as active loads, and they can also be used as pull-up transistors instead of resistors, in this case, it is a four-transistor static random access memory (4t-SRAM). In addition, in this embodiment, a source region of each of the first pull-up transistor PU1 and the second pull-up transistor PU2 is electrically connected to a voltage source Vcc, and a source region of each of the first pull-down transistor PD1 and the second pull-down transistor PD2 is electrically connected to a voltage source Vss.

In an embodiment, the first pull-up transistor PU1 and the second pull-up transistor PU2 of the SRAM cell 10 are composed of P-type metal oxide semiconductor (PMOS) transistors. The first pull-down transistor PD1, the second pull-down transistor PD2, the first access transistor PG1 and the second access transistor PG2 are composed of N-type metal oxide semiconductor (NMOS) transistors, but the present invention is not limited to this. The first pull-up transistor PU1 and the first pull-down transistor PD1 together form an inverter, and two terminals of the series circuit formed by them are respectively coupled to a voltage source Vcc and a voltage source Vss, similarly, the second pull-up transistor PU2 and the second pull-down transistor PD2 form another inverter, and two terminals of the series circuit formed by them are also coupled to the voltage source Vcc and the voltage source Vss respectively. The two inverters are coupled to each other to store data.

In addition, the storage node N1 is electrically connected with the gate of the second pull-down transistor PD2, the gate of the second pull-up transistor PU2, the drain of the pull-down transistor PD1, the drain of the first pull-up transistor PU1, and the drain of the first access transistor PG1, respectively. Similarly, the storage node N2 is also electrically connected with the gate of the first pull-down transistor PD1, the gate of the first pull-up transistor PU1, the drain of the second pull-down transistor PD2, the drain of the second pull-up transistor PU2 and the drain of the second access transistor PG2, respectively. As for the first access transistor PG1 and the second access transistor PG2, the gates are respectively coupled to the word line WL, while the source of the first access transistor PG1 and the source of the second access transistor PG2 are respectively coupled to the corresponding bit line BL1 and BL2.

In this embodiment, as shown in FIG. 1, the body of the first pull-down transistor PD1 is connected to the body of the first access transistor PG1, and the two bodies are commonly connected to the voltage source Vss. Similarly, the body of the second pull-down transistor PD2 is connected to the body of the second access transistor PG2, and two bodies are commonly connected to the voltage source Vss. In this way, the charges stored in the substrate of the pull-down transistors PD1 and PD2 and the access transistors PG1 and PG2 can be prevented from affecting the electrical properties of the transistors, which will be described in the following paragraphs in detail.

The SRAM cell 10 includes six transistors, so it can also be called a six-transistor static random access memory (6T-SRAM). However, the SRAM cell of the present invention is not limited to 6T-SRAM, and other SRAM patterns with more transistors, such as 8T-SRAM and 10T-SRAM, can also be used as the SRAM cell of the present invention.

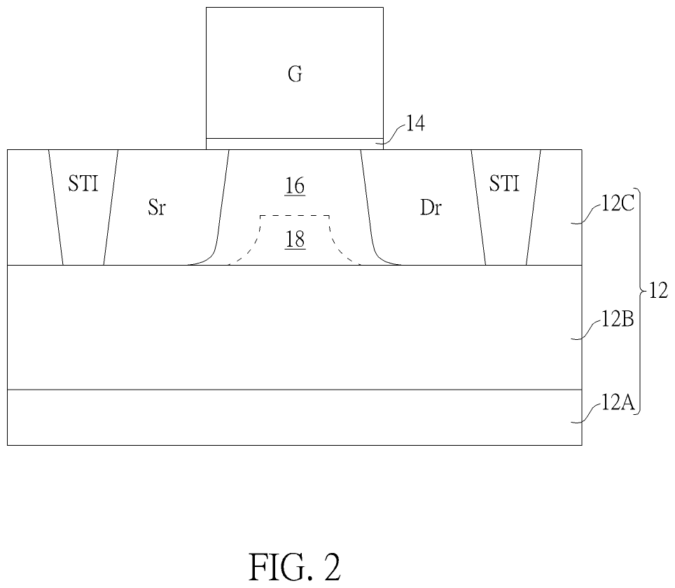

When a transistor is formed on a silicon-on-insulator (SOI) substrate, some charges may accumulate under the gate structure and be restricted, and the accumulated charges will cause electrical instability of the transistor. In more detail, FIG. 2 shows a schematic cross-sectional structure of a transistor. As shown in FIG. 2, the substrate 12 is an SOI substrate, which includes a silicon layer 12A, an insulating layer 12B and a silicon layer 12C stacked from bottom to top. The gate structure POLY is located on the substrate 12, and a gate dielectric layer 14 is included between the gate structure POLY and the substrate 12. The substrate 12 on both sides of the gate structure respectively include a source Sr and a drain Dr, and shallow trench isolation (STI) is located outside the source Sr and the drain Dr. A depletion region 16 is included under the gate structure POLY and between the source Sr and the drain Dr. However, there is a region 18 under the depletion region 16 between the depletion region 16 and the insulating layer 12B, and some charges may accumulate in the region 18, but these charges cannot be discharged from the region 18, and the charges accumulated in the region 18 may affect the electrical properties of the transistor.

In order to solve the above problems, in some embodiments, the diffusion regions under the pull-down transistors PD1 and PD2 and the access transistors PG1 and PG2 will be extended, so that the charges under the gates can be released through the diffusion regions. Details will be described in the following paragraphs.

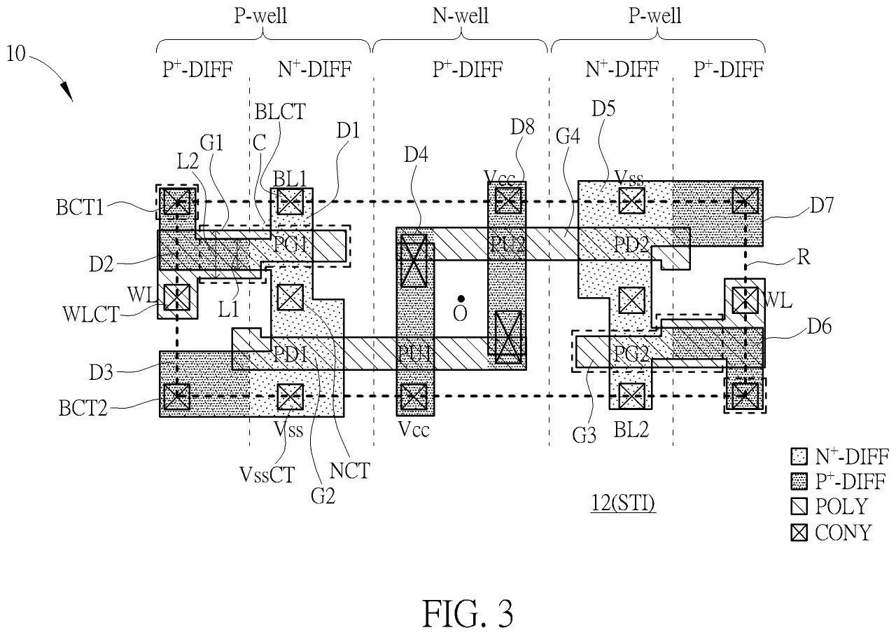

FIG. 3 is a layout diagram of a static random access memory (SRAM) cell according to a first preferred embodiment of the present invention. In this embodiment, the SRAM cell 10 is located in a region R and is arranged on a substrate 12, such as a silicon-on-insulator (SOI) substrate. A plurality of N-type diffusion regions N+-DIFF and a plurality of P-type diffusion regions P+-DIFF are arranged on the substrate 12, which will be together referred to as diffusion regions DIFF, and the shallow trench isolation STI is arranged around each diffusion region DIFF.

In addition, the substrate 12 includes a plurality of gate structures POLY, and each transistor (including the first pull-up transistor PU1, the second pull-up transistor PU2, the first pull-down transistor PD1, the second pull-down transistor PD2, the first access transistor PG1 and the second access transistor PG2) includes a gate structure G spanning at least one diffusion region DIFF to form each transistor.

As shown in FIG. 3, in order to clearly define the positions of each gate structure POLY and diffusion region DIFF, the gate structures POLY are defined as a first gate structure G1, a second gate structure G2, a third gate structure G3 and a fourth gate structure G4, and the diffusion regions D are also defined as a first diffusion region D1, a second diffusion region D2, a third diffusion region D3, a fourth diffusion region D4, a fifth diffusion region D5, a sixth diffusion region D6, a seventh diffusion region D7 and a eighth diffusion region D8. The first gate structure G1 spans the first diffusion region D1 to form the first access transistor PG1; the second gate structure G2 spans the first diffusion region D1 to form a first pull-down transistor PD1; the second gate structure G2 spans the fourth diffusion region D4 to form the first pull-up transistor PU1; the third gate structure G3 spans the fifth diffusion region D5 to form a second access transistor PG2; the fourth gate structure G4 spans the fifth diffusion region D5 to form a second pull-down transistor PD2; the fourth gate structure G4 spans the eighth diffusion region D8 to form the second pull-up transistor PU2. It can be understood that the first gate structure G1, the second gate structure G2, the third gate structure G3 and the fourth gate structure G4 all belong to the gate structure G, while the first diffusion region D1, the second diffusion region D2, the third diffusion region D3, the fourth diffusion region D4, the fifth diffusion region D5, the sixth diffusion region D6, the seventh diffusion region D7 and the eighth diffusion region D8 all belong to the diffusion region DIFF. In the present invention, the first gate structure G1, the second gate structure G2, the third gate structure G3 and the fourth gate structure G4 are preferably arranged along the first direction (for example, the X-axis direction).

In addition, in this embodiment, the end of the second gate structure G2 (one end close to the first pull-down transistor PD1) is designed as an L-shape, that is, the end of the second gate structure G2 has a protruding part. Similarly, the end of the fourth gate structure G4 (one end near the second pull-down transistor PD2) is also designed as an L-shape, that is, the end of the fourth gate structure G4 has a protruding part. However, the present invention is not limited to this. In other embodiments of the present invention, the second gate structure G2 and the fourth gate structure G4 can also be designed into different shapes according to requirements, such as straight line shapes, which are within the scope of the present invention.

In the region R, there are also a plurality of metal layers (not shown) and contact structures CONT. The metal layers and contact structures CONT are mainly used to electrically connect transistors with other elements, such as word lines, bit lines and voltage sources, or to connect storage nodes as interconnection structures of transistors. The material of the metal layer and the contact structure CONT is, for example, metal, and they may have the same material. For the sake of simplicity, the positions of some metal layers are not drawn in FIG. 3, but for the sake of clearer explanation, transistors, word lines, bit lines, voltage sources, etc. connected to each element are marked next to each element in FIG. 3 to clearly show the connection relationship of each element.

In addition, in the embodiment of FIG. 3, since the first pull-down transistor PD1, the second pull-down transistor PD2, the first access transistor PG1, and the second access transistor PG2 are composed of N-type MOS transistors, the diffusion regions DIFF that they straddle are also N-type doped diffusion regions and are located on P-well of the substrate 12. On the contrary, since the first pull-up transistor PU1 and the second pull-up transistor PU2 are composed of P-type MOS transistors, the diffusion regions DIFF they span are also P-type doped diffusion regions, and are located on N-well of the substrate 12. That is, as shown in FIG. 2, the first diffusion region D1 and the fifth diffusion region D5 are N-type diffusion regions, while the second diffusion region D2, the third diffusion region D3, the fourth diffusion region D4, the sixth diffusion region D6, the seventh diffusion region D7 and the eighth diffusion region D8 are P-type diffusion regions, and the substrate 12 directly below each gate structure G1-G4 is a P-well or an N-well. In FIG. 3, the diffusion region within the dashed line range N+ is an N-type diffusion region, and the diffusion region within the dashed line range P+ is a P-type diffusion region. That is to say, “N+-DIFF” in FIG. 3 represents the N-type diffusion region and “P+-DIFF” represents the P-type diffusion region, and the N-type diffusion region and the P-type diffusion region are represented by different patterns. In addition, in FIG. 3, the range of P-well and N-well of the substrate 12 is also marked, which covers the portion of the substrate 12 directly below each gate structure G1-G4 except the shallow trench isolation STI and the doped region.

In the layout pattern shown in FIG. 3, the pattern of the left half (including the first pull-up transistor PU1, the first pull-down transistor PD1 and the first access transistor PG1) and the pattern of the right half (including the second pull-up transistor PU2, the second pull-down transistor PD2 and the second access transistor PG2) are symmetrically distributed along the center point O. Therefore, in the following paragraph description, the pattern characteristics of the left half will be described emphatically, while the patterns of the right half have the same characteristics, so they will not be repeated here.

In addition, as shown in FIG. 3, The contact structures CONT also include a first body contact BCT1 located on the second diffusion region D2 (as indicated by the dotted line), a second body contact BCT2 located on the third diffusion region D3, a word line contact WLCT located on the first gate structure G1 and electrically connected with the word line WL, a bit line contact BLCT located on the first diffusion region D1 and electrically connected with the bit line BL1, a Vss voltage source contact VssCT located on the first diffusion region D1 and electrically connected with the voltage source Vss, and a node contact NCT located on the first diffusion region D1 and between the first gate structure G1 and the second gate structure G2. It can be understood that the first body contact BCT1, the second body contact BCT2, the word line contact WLCT, the bit line contact BLCT, the Vss voltage source contact VssCT and the node contact NCT all belong to the contact structures CONT. In addition, all the above contact structures are located in the left half of the pattern, but because the layout pattern of this embodiment is symmetrical, the right half also has the same contact structures, but these contact structures are omitted and not described.

In this embodiment, both the second diffusion region D2 and the third diffusion region D3 are connected to the first diffusion region D1, wherein the second diffusion region D2 has a complementary conductivity type to the first diffusion region D1 (for example, the second diffusion region D2 is P-type and the first diffusion region D1 is N-type). Similarly, the third diffusion region D3 has a complementary conductivity type to the first diffusion region D1 (for example, the third diffusion region D3 is P-type and the first diffusion region D1 is N-type). With this configuration, the charge accumulated under the gate of the transistor can be released through the adjacent and electrically complementary diffusion regions.

Taking the first access transistor PG1 as an example, since the gate structure G1 of the first access transistor PG1 spanning the first diffusion region D1 is N-type, the source Sr and the drain Dr of the first access transistor PG1 are also N-type. Therefore, P-type charges will accumulate in the region directly below the gate structure and be restricted by the N-type source Sr and the drain Dr, and these charges will be restricted directly below the gate structure and cannot be discharged in the embodiment shown in FIG. 2. However, by the improved design of the present invention, as shown in FIG. 3, the P-type charge directly below the gate structure of the first access transistor PG1 can flow out through the second diffusion region D2 which is also P-type, and then be connected to the first body contact BCT1 through the metal silicide layer (not shown) formed on the surfaces of the diffusion regions D1-D8, so that the charges can be released. Similarly, the charges (P-type charges) accumulated directly under the gate structure of the first pull-down transistor PD1 will also flow out through the P-type third diffusion region D3, and then be connected to the second body contact BCT2 through the metal silicide layer (not shown), so that the charges can be released. As for the second pull-down transistor PD2 and the second access transistor PG2, the accumulated charges can flow out from the seventh diffusion region D7 and the sixth diffusion region D6, respectively. Since the second pull-down transistor PD2 and the second access transistor PG2 are the symmetrical patterns of the first pull-down transistor PD1 and the first access transistor PG1 along the center point O, they are not repeated here.

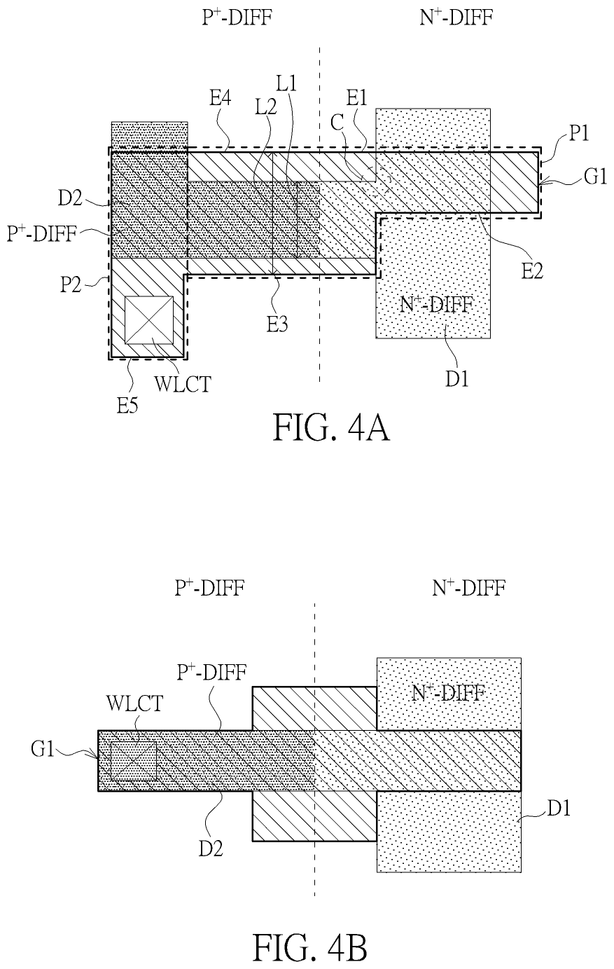

Another feature of this embodiment is that the shape of the first gate structure G1 (and the symmetrical third gate structure G3) is a special stepped shape. For example, in FIG. 3, the first gate structure G1 is framed by a dotted line. Please refer to FIG. 4A for more details. FIG. 4A shows an enlarged schematic diagram of the first gate structure G1 and its vicinity in FIG. 3. Please note that for the sake of simplicity, only the first gate structure G1, the first diffusion region D1 and the second diffusion region D2 are drawn in FIG. 4A, and the other elements are omitted. As shown in FIG. 4A, the first gate structure G1 has a stepped shape. More specifically, the first gate structure G1 includes an L-shaped first part P1 and a long second part P2, wherein the first part P1 includes a first edge E1, a second edge E2 and a third edge E3, all of which are arranged along a first direction (for example, the X direction). The second part P2 includes a fourth edge E4 and a fifth edge E5, both of them are arranged along the first direction (X direction). The first edge E1 is aligned with the fourth edge E4, but the second edge E2, the third edge E3 and the fourth edge E4 are not aligned with each other.

In this embodiment, the first gate structure G1 is designed to be stepped shape, which has some advantages compared with other gates. For example, please refer to FIG. 4B, which shows an enlarged schematic diagram of the first gate structure G1 and its vicinity in another embodiment. In the embodiment shown in FIG. 4B, the first gate structure G1 is designed in a cross shape. Compared with the cross-shaped first gate structure G1 pattern shown in FIG. 4B, the stepped first gate structure G1 pattern shown in FIG. 4A contains less right-angle parts, so that the occurrence probability of rounding can be reduced when the pattern is formed, and the gate length or gate width of each transistor can be prevented from being changed due to rounding. In addition, the first gate structure G1 shown in FIG. 4A is flat at the boundary (i.e., the upper boundary) from the region R, so when a plurality of SRAM cells are arranged, the first gate structure G1 can keep a larger distance from other adjacent gate structures, and the probability of short circuit due to mutual contact of the gate structures is reduced.

In addition, the first gate structure G1 as shown in FIG. 4A includes a second part P2 extending downward (negative Y direction), wherein the word line contact WLCT is located on the second part P2, but does not overlap with the second diffusion region D2. In this way, the problem that the word line contact WLCT contacts the second diffusion region D2 to cause short circuit when the word line contact WLCT is offset can be avoided. On the other hand, in the pattern shown in FIG. 4B, the word line contact WLCT and the second diffusion region D2 overlap with each other (with the first gate structure G1 between them). However, if the position of the second diffusion region D2 or the word line contact WLCT is shifted due to alignment problems in the manufacturing process, the second diffusion region D2 and the word line contact WLCT may contact at a part other than the first gate structure G1, resulting in a short circuit. Therefore, as in the pattern designed in FIG. 4A, the word line contact WLCT is designed to be located on the second part P2 but not overlapped with the second diffusion region D2, which can effectively avoid the above alignment problem.

Besides, according to the structures in FIGS. 3 and 4A, the present invention has several features. Firstly, the diffusion region (e.g., the first diffusion region D1) of the present invention has a corner portion C, and the corner portion C is covered by the first gate structure G1, that is, the corner portion C of the first diffusion region D1 overlaps with the first gate structure G1. Due to the symmetry of the pattern, the fifth diffusion region D5 will also have a corner portion overlapping with the third gate structure G3. In this way, the corner of the diffusion region is covered by the gate structure, which has the risk of reducing leakage current.

In addition, please refer to FIGS. 3 and 4A. In the pattern of the present invention, the length of the boundary between the first diffusion region D1 and the second diffusion region D2 is defined as L1, and the length of the part of the stepped first gate structure G1 covering the boundary is defined as L2, where L2 is greater than L1. That is to say, from the top view, the stepped first gate structure G1 completely covers the boundary between the first diffusion region D1 and the second diffusion region D2. Because leakage current is easy to be generated at the boundary of diffusion regions with different conductivity types, this embodiment completely covers the boundary of diffusion regions with different conductivity types, which can reduce the probability of leakage current generated at the boundary of diffusion regions through metal silicide.

In addition, in order to improve the uniformity of the overall pattern, as shown in FIG. 3, it is preferable that the distance from the upper edge of the word line contact WLCT to the first body contact BCT1 in the second direction (Y direction) in this embodiment is equal to the distance from the lower edge of the word line contact WLCT to the second body contact BCT2 in the second direction (Y direction). In addition, the distance from the first body contact BCT1 to the bit line contact BLCT in the first direction (X direction) is equal to the distance from the second body contact BCT2 to the Vss voltage source contact VssCT in the first direction (X direction), and also equal to the distance from the word line contact WLCT to the node contact NCT1 in the first direction (X direction).

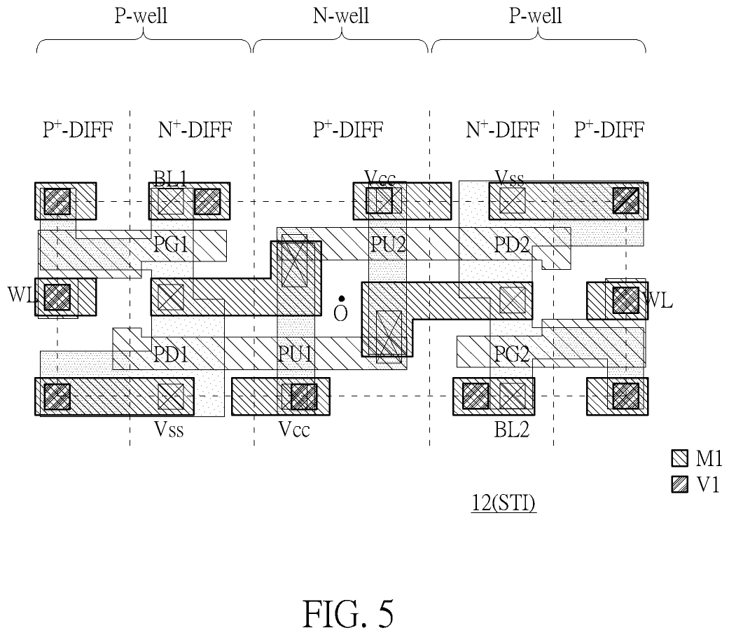

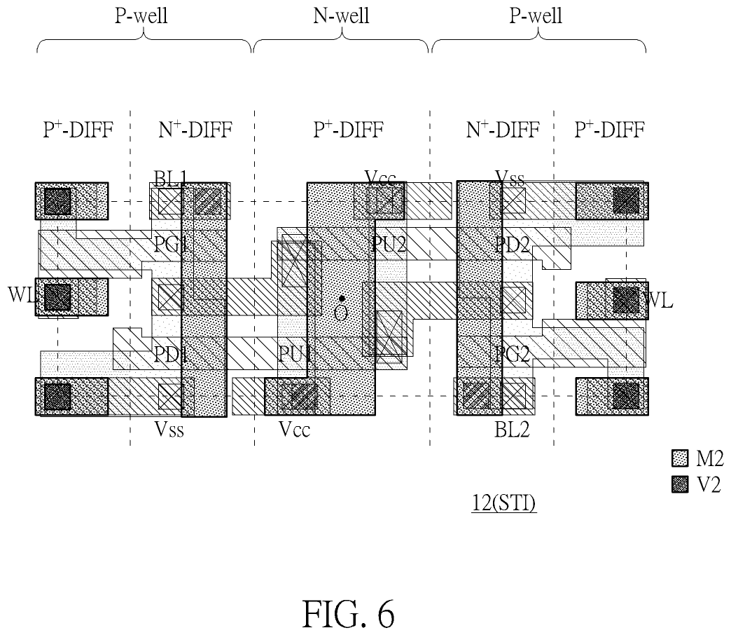

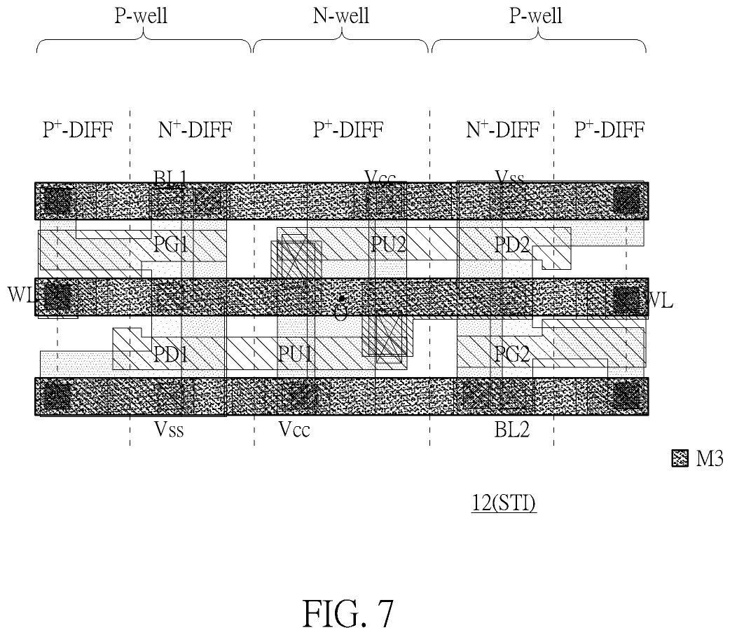

Subsequently, as shown in FIGS. 5, 6 and 7, a plurality of first metal layers M1, a plurality of first contact plugs (via) V1, a plurality of second metal layers M2, a plurality of second contact plugs V2 and a plurality of third metal layers M3 are sequentially formed on the SRAM cell layout shown in FIG. 3. The function of the metal layers and the contact plugs are to connect each transistor or storage nodes to other voltage sources or components, or to connect different terminals of each transistor with each other. The material of the metal layers and the contact plugs are, for example, metals with good conductivity, such as copper and tungsten, but it is not limited to this. It is worth noting that the first body contact BCT1, the second body contact BCT2 and the voltage source Vss will be connected with the contact plug through the above metal layer, thus achieving the effect of discharging charges. More specifically, in this embodiment, since the first pull-down transistor PD1 and the first access transistor PG1 each include a body contact, and the second pull-down transistor PD2 and the second access transistor PG2 each include a body contact, these four body contacts will be connected to the voltage source Vss through the third metal layer M3. Other features related to the contact plug and the metal layer are known in the art, and will not be described here.

Based on the above description and drawings, the present invention provides a layout pattern of a static random-access memory (SRAM) cell 10, which comprises a substrate 12 on which a plurality of diffusion regions (N+-DIFF or P+-DIFF) are located. The diffusion regions DIFF at least includes a first diffusion region D1, a second diffusion region D2, a third diffusion region D3 and a fourth diffusion region D4, and a plurality of gate structures POLY are located on the substrate, and each gate structure POLY extends along a first direction (X direction) and spans the plurality of diffusion regions DIFF to form a plurality of transistors. The plurality of transistors comprise a first pull-up transistor (PU1), a first pull-down transistor (PD1), a second pull-up transistor (PU2), a second pull-down transistor (PD2), a first access transistor (PG1) and a second access transistor (PG2), the plurality of gate structures POLY comprises a first gate structure G1, and when viewed from a top view, the first gate structure G1 has a stepped shape. The first gate structure G1 spans the first diffusion region D1 and the second diffusion region D2 to form the first access transistor (PG1), wherein the first diffusion region D1 is adjacent to and in direct contact with the second diffusion region D2.

In some embodiments of the present invention, the first gate structure G1 further includes a first part P1 and a second part P2. When viewed from the top view, the first part P1 has an L-shape, and the second part P2 has a strip shape.

In some embodiments of the present invention, the first part P1 has a first edge E1, a second edge E2 and a third edge E3 extending along the first direction (X direction), and the second part P2 has a fourth edge E4 and a fifth edge E5 extending along the first direction (X direction).

In some embodiments of the present invention, the first edge E1 and the fourth edge E4 are in contact with each other and aligned in the first direction.

In some embodiments of the present invention, the sum of the length of the first edge E1 and the length of the fourth edge E4 is equal to the sum of the length of the second edge E2, the length of the third edge E3 and the length of the fifth edge E5.

In some embodiments of the present invention, the width of the second diffusion region D2 in a second direction (Y direction) is smaller than the distance of the first edge E1 to the third edge E3 in the second direction (Y direction), wherein the second direction is perpendicular to the first direction (please refer to FIG. 4A).

In some embodiments of the present invention, the first part P1 overlaps with the first diffusion region D1 and the second diffusion region D2, and the second part P2 overlaps with the second diffusion region D2.

In some embodiments of the present invention, a second gate structure G2 spans the first diffusion region D1 and the third diffusion region D3 to form a first pull-down transistor (PD1), wherein the first diffusion region D1 is adjacent to and in direct contact with the third diffusion region D3.

In some embodiments of the present invention, the second diffusion region D2 is not in direct contact with the third diffusion region D3.

In some embodiments of the present invention, the second gate structure G2 spans the fourth diffusion region D4 to form the first pull-up transistor (PU1).

In some embodiments of the present invention, the first diffusion region D1 contains a first conductivity type (e.g., N type), and the second diffusion region D2, the third diffusion region D3 and the fourth diffusion region D4 contain a second conductivity type (e.g., P type).

In some embodiments of the present invention, a word line contact WLCT is further included, which is electrically connected to the first gate structure G1, wherein the word line contact WLCT does not overlap with the second diffusion region D2 when viewed from the top view.

In some embodiments of the present invention, a first body contact BCT1 is further included, which is located on and electrically connected to the second diffusion region D2.

In some embodiments of the present invention, a second body contact BCT2 is further included, which is located on and electrically connected with the third diffusion region D3.

In some embodiments of the present invention, the spacing between the word line contact WLCT and the first body contact BCT1 in the second direction (Y direction) is equal to the spacing between the word line contact WLCT and the second body contact BCT2 in the second direction, wherein the second direction is perpendicular to the first direction.

In some embodiments of the present invention, the first body contact BCT1, the second body contact BCT2 and the word line contact WLCT are aligned with each other in the second direction.

In some embodiments of the present invention, the word line contact WLCT is not aligned with the first part P1 in the first direction (for example, in FIG. 3, the word line contact WLCT is located at the lower left of the first part P1 and is not aligned in the horizontal direction).

In some embodiments of the present invention, it further includes a bit line contact BLCT electrically connected to the first diffusion region D1 and a source of the first access transistor (PG1), and a Vss voltage source contact VssCT electrically connected to the first diffusion region D1 and a source of the first pull-down transistor (PD1) (please refer to FIGS. 1 and 3).

In some embodiments of the present invention, a node contact NCT is further included, which is electrically connected to the first diffusion region D1 and located between the first gate structure G1 and the second gate structure G2.

In some embodiments of the present invention, the bit line contact BLCT, the Vss voltage source contact VssCT and the node contact NCT are aligned with each other in the second direction (Y direction).

The present invention is characterize by providing an improved layout pattern of static random access memory, which include some diffusion regions with opposite electrical properties, which are located beside that diffusion region below the gate of each transistor. In this way, the charge accumulated under the gate structure can flow out through the diffusion region, and then the charge is released through the contact structure, so as to avoid affecting the electrical properties of the transistor and improve the product yield. In addition, the gate structure is designed in a stepped shape (from the top view), which has the advantages of avoiding the close distance between adjacent gates, staggering the word line contact with the diffusion region, reducing the rounding of the pattern, and so on, so the process yield can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout pattern of a static random-access memory (SRAM), comprising:
a substrate;
a plurality of diffusion regions located on the substrate, and the plurality of diffusion region at least comprises a first diffusion region, a second diffusion region, a third diffusion region and a fourth diffusion region;
a plurality of gate structures located on the substrate, and each gate structure extends along a first direction (X direction) and crosses the diffusion regions to form a plurality of transistors, wherein the plurality of transistors comprise a first pull-up transistor (PU1), a first pull-down transistor (PD1), a second pull-up transistor (PU2), a second pull-down transistor (PD2), a first access transistor (PG1) and a second access transistor (PG2), wherein the plurality of gate structures comprise a first gate structure, which has a stepped shape when viewed from a top view, and the first gate structure spans the first diffusion region and the second diffusion region to form the first access transistor (PG1), wherein the first diffusion region is adjacent to and in direct contact with the second diffusion region.

2. The layout pattern of the SRAM according to claim 1, wherein the first gate structure further comprises a first part and a second part, the first part has an L-shape and the second part has a strip shape when viewed from the top view.

3. The layout pattern of SRAM according to claim 2, wherein the first part has a first edge, a second edge and a third edge extending along the first direction, and the second part has a fourth edge and a fifth edge extending along the first direction.

4. The layout pattern of the SRAM according to claim 3, wherein the first edge and the fourth edge are in contact with each other and aligned in the first direction.

5. The layout pattern of SRAM according to claim 3, wherein the sum of the length of the first edge and the length of the fourth edge is equal to the sum of the length of the second edge, the length of the third edge and the length of the fifth edge.

6. The layout pattern of SRAM according to claim 3, wherein the width of the second diffusion region in a second direction (Y direction) is smaller than the distance from the first edge to the third edge in the second direction, wherein the second direction is perpendicular to the first direction.

7. The layout pattern of SRAM according to claim 2, wherein the first part overlaps with the first diffusion region and the second diffusion region, and the second part overlaps with the second diffusion region, and the first diffusion region has a corner portion, wherein the corner portion overlaps with the first part.

8. The layout pattern of the SRAM according to claim 1, further comprising a second gate structure spanning the first diffusion region and the third diffusion region to form the first pull-down transistor (PD1), wherein the first diffusion region is adjacent to and in direct contact with the third diffusion region.

9. The layout pattern of the SRAM according to claim 8, wherein the second diffusion region does not contact the third diffusion region directly.

10. The layout pattern of the SRAM according to claim 8, wherein the second gate structure spans the fourth diffusion region to form the first pull-up transistor (PU1).

11. The layout pattern of the SRAM according to claim 1, wherein the first diffusion region comprises a first conductivity type, and the second diffusion region, the third diffusion region and the fourth diffusion region comprise a second conductivity type.

12. The layout pattern of the SRAM according to claim 2, further comprising a word line contact electrically connected to the first gate structure, wherein the word line contact does not overlap the second diffusion region from the top view.

13. The layout pattern of the SRAM according to claim 12, further comprising a first body contact located on and electrically connected to the second diffusion region.

14. The layout pattern of the SRAM according to claim 13, further comprising a second body contact located on and electrically connected to the third diffusion region.

15. The layout pattern of SRAM according to claim 14, wherein the distance between the word line contact and the first body contact in a second direction (Y direction) is equal to the distance between the word line contact and the second body contact in the second direction, wherein the second direction is perpendicular to the first direction.

16. The layout pattern of the SRAM according to claim 15, wherein the first body contact, the second body contact and the word line contact are aligned with each other in the second direction.

17. The layout pattern of the SRAM according to claim 12, wherein the word line contact and the first part are not aligned in the first direction.

18. The layout pattern of the SRAM according to claim 1, further comprising a bit line contact electrically connecting the first diffusion region and a source of the first access transistor (PG1), and a Vss voltage source contact electrically connecting the first diffusion region and a source of the first pull-down transistor (PD1).

19. The layout pattern of the SRAM according to claim 18, further comprising a node contact electrically connected to the first diffusion region and located between the first gate structure and a second gate structure.

20. The layout pattern of the SRAM according to claim 19, wherein the bit line contact, the Vss voltage source contact and the node contact are aligned with each other in a second direction (Y direction).
